(19) United States
(12) Patent Application Publication
(10) Pub. No.: US 2026/0293709 A1
(43) Pub. Date: Sep. 24, 2026

(54) SEMICONDUCTOR DEVICE MODULE WITH MODULAR PIN ASSEMBLY AND METHODS OF MANUFACTURE

(71) Applicant: SEMICONDUCTOR COMPONENTS INDUSTRIES, LLC, Scottsdale, AZ (US)

(72) Inventors: Jerome TEYSSEYRE, Singapore (SG); Chee Hiong CHEW, Seremban (MY); Seungwon IM, Bucheon (KR)

(73) Assignee: SEMICONDUCTOR COMPONENTS INDUSTRIES, LLC, Scottsdale, AZ (US)

(21) Appl. No.: 19/085,016

(22) Filed: Mar. 20, 2025

(51) Int. Cl. H01L 23/495; H01L 21/48; H01L 23/31

(52) U.S. Cl. CPC H10W 70/464; H10W 70/041; H10W 74/111

(57) ABSTRACT

A semiconductor device assembly may include a module that includes: a molding compound layer and a substrate located inside of the molding compound layer, a semiconductor die electrically coupled with the substrate, a leadframe coupled with the substrate, the leadframe including a pin terminal extending from the molding compound layer; and a pin assembly including: a base coupled to the module, the base including a pin socket and a pin terminal opening, the pin terminal disposed in the pin terminal opening; and a pin disposed in the pin socket and coupled to the pin terminal.

### BACKGROUND

Semiconductor device assemblies, such as assemblies including power semiconductor devices (which can be referred to as power modules, multi-chip power modules, etc.), can be implemented using semiconductor die, substrates (e.g., direct-bonded metal substrates, ceramic substrates, and so forth), wire bonds, etc. Such semiconductor device assemblies can be coupled with a printed circuit board (PCB) of an electrical system, such as an inverter system, by pins. The pins may be solder pins which are soldered to the PCB or press-fit pins which are press-fit into plated through holes in the PCB.

### SUMMARY

In some aspects, the techniques described herein relate to a semiconductor device assembly, including: a module that includes: a semiconductor die electrically coupled with a substrate; a leadframe coupled with the substrate and the semiconductor die; and a molding compound encapsulating the substrate, the semiconductor die and the leadframe, wherein the leadframe includes a pin terminal extending from the molding compound; and a pin assembly including: a base coupled to the module; and a pin disposed in a pin socket of the base; wherein the pin terminal is inserted into the base and a terminal end of the pin is coupled to the pin terminal.

In some aspects, the techniques described herein relate to a pin assembly, including: a base that includes a pin socket in a top side of the base and a pin terminal opening in a first side of the base; and a pin configured to be disposed in the pin socket, wherein the pin includes a non-conductive body that is configured to be inserted into the pin socket; wherein the pin terminal opening intersects the pin socket and is configured to receive a pin terminal of a semiconductor device assembly for coupling the pin to the pin terminal.

In some aspects, the techniques described herein relate to a method for producing a semiconductor device assembly, the method including: electrically coupling a semiconductor die with a substrate; coupling a leadframe with the substrate; applying a molding compound to the leadframe and the substrate to form a module that includes a pin terminal extending from a side of the module; coupling a base of a pin assembly to the module by inserting the pin terminal into the base; inserting a pin into a pin socket of the base; and coupling the pin to an end portion of the pin terminal located in the base.

### BRIEF DESCRIPTION OF THE DRAWINGS

FIG. 1A is a front view of an example semiconductor device assembly of the present disclosure.

FIGS. 1B to 1D are, respectively, a front view, a first side view, and a bottom view of an example semiconductor device assembly of the present disclosure.

FIG. 2 is a front view of the semiconductor device assembly of FIGS. 1B-1D showing first and second pin assemblies spaced from a module portion of the semiconductor device assembly.

FIG. 3A is a cross-sectional side view of the semiconductor device assembly of FIG. 1A taken along section line 3-3 of FIG. 1B.

FIG. 3B is a cross-sectional side view of the semiconductor device assembly of FIG. 1A taken along section line 3-3 of FIG. 1B with the pins removed.

FIG. 3C is an end cross-sectional detail view of the semiconductor device assembly of FIGS. 1B-1D showing one of the pins in an inserted position and coupled to a pin terminal.

FIG. 3D is a front view of one of the pins of the of the semiconductor device assembly of FIGS. 1B-1D.

FIGS. 4A and 4B are, respectively, front and side views of a pin of the present disclosure.

FIGS. 5A and 5B are, respectively, front and side views of a pin of the present disclosure.

FIGS. 5C and 5D are, respectively, front and side views of the pin of FIGS. 5A and 5B and a detail cross-sectional view of a portion of an electrical system into which the pin is inserted.

FIG. 6A is a front view of an example substrate assembly of the semiconductor device assembly of FIGS. 1B-1D.

FIG. 6B is a front view of the semiconductor device assembly of FIGS. 1B-1D prior to a mold operation.

FIG. 7 is a front view of an example transfer molding press-fit pin frame assembly.

FIGS. 8A to 8C are, respectively, a front view, a first side view, and a bottom view of an example semiconductor device assembly.

FIGS. 9A to 9D are, respectively, a front view, a first side view, a second side view, and a bottom view of an example semiconductor device assembly.

FIGS. 10A to 10D are, respectively, a front view, a first side view, a second side view, and a bottom view of an example semiconductor device assembly.

FIG. 11 is a flowchart illustrating an example method for producing a semiconductor device assembly of the present disclosure.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

This disclosure relates to packaged semiconductor device apparatuses, which can be referred to as semiconductor device modules as well as associated methods for producing such apparatuses. The approaches illustrated and described herein can be used to implement molded (e.g., transfer molded) semiconductor device modules that can overcome at least some of the drawbacks of prior modules. In some implementations, the described approaches can be used to implement, for example, a half-bridge power module, a full-bridge power module, a 3-phase half-bridge power module, a multi-phase half-bridge power module, etc., which can be used in automotive application, industrial applications, and/or consumer electronics applications. In some implementations, the semiconductor device modules can be referred to as assemblies, modules, power semiconductor device modules, semiconductor device assemblies, electronic device assemblies, etc.,

At least one technical problem with prior power module implementations with press fit pins is an overall cost and complexity associated with the components used to couple the fins to the power module. Another technical problem is the manufacturing cost and complexity of coupling pins to a leadframe of the power module. Another technical problem is the lack of flexibility of the number and location of the pins with respect to the module package.

At least one technical solution to the foregoing technical problems is to implement such power modules using a modular pin assembly that is separate from the power module and can be easily attached to the power module, for example, near the end of a fabrication process.

Technical benefits in accordance with the foregoing technical solutions include a reduction in manufacturing costs and complexity, a reduction in the overall size of the power module, and an increase in design flexibility, where the same power module can be used for applications with different pin requirements by varying the design of the modular pin assembly.

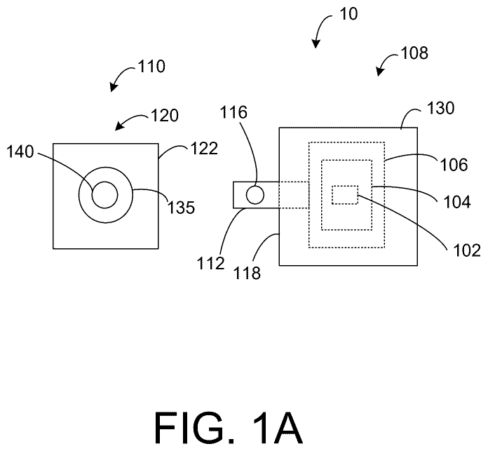

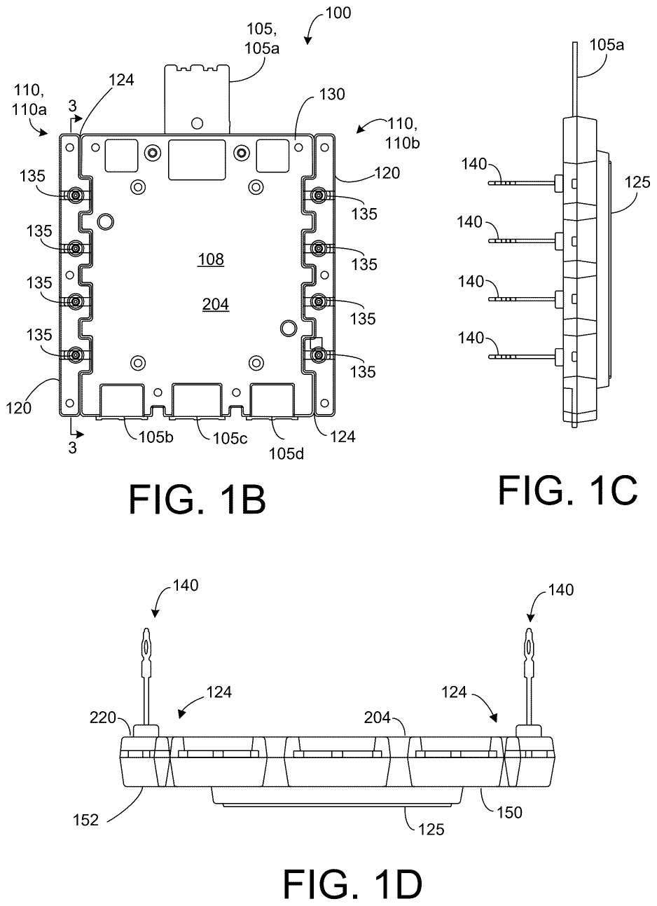

FIG. 1A is a front view of an example semiconductor device assembly 10 made in accordance with the present disclosure. In the illustrated example, semiconductor device assembly 10 may include a module 108 which may include a semiconductor die 102 electrically coupled with a substrate 104. Semiconductor device assembly 10 may also include a leadframe 106 coupled with the substrate 104 and the semiconductor die 102. Semiconductor device assembly 10 may also include a molding compound 130 that encapsulates the substrate 104, the semiconductor die 102 and the leadframe 106.

In the illustrated example, the semiconductor device assembly 10 is a press-fit pin package design in which at least one pin 140 extends vertically from the semiconductor device assembly 10. The semiconductor device assembly 10 may be configured to be coupled to a PCB of an electrical system (not illustrated) at least in part by solderless press-fit pin connections via the pin(s) 140. In the illustrated example, the pin 140 may be part of a pin assembly 110 that is configured to be coupled to the module 108. In the illustrated example, the pin assembly 110 includes a base 120 that may be formed from a molding compound. The base 120 may define a pin socket 135 which includes an opening in the base 120 in which an end of the pin 140 is inserted. FIG. 1A shows an example semiconductor device assembly 10 with one pin socket 135. In an example, a pin assembly of the present disclosure may include any number of pin sockets and corresponding pins. As described herein, the modular nature of the pin assembly 110 provides a number of benefits, including reduced manufacturing cost and complexity and increased design flexibility.

In some implementations, the molding compound 130 and/or base 120 may be formed from a molding material or compound, an encapsulation material, and the like and can be, or can include a non-conducting layer or material. In some implementations, the molding compound 130 and/or the base 120 is formed from a non-conducting material, such as an epoxy, which can be formed (applied, etc.) using a transfer molding process or a compression molding process in conjunction with corresponding tooling, e.g., a molding jig. In some implementations, the molding compound can include a separate plastic housing that is included in the semiconductor device assembly.

Module 108 may also include at least one pin terminal 112 that may be coupled to leadframe 106 and that may be designed and configured to mechanically and electrically couple to the pin 140. In an example, the pin terminal 112 extends out from the molding compound 130 of the module 108. In an example, the pin terminal 112 includes a pin opening 116 that is designed and configured to receive a first end, or terminal end, of the pin 140. In an example, opening 116 is spaced from a side 118 of the molding compound 130 of the module 108 by a distance such that the opening 116 is aligned with pin socket 135 and pin 140 when the pin assembly 110 is coupled to the module 108.

FIG. 1A shows the pin assembly 110 removed from the module 108. During an example assembly or manufacturing process, the pin terminal 112 can be inserted into the base 120 of the pin assembly 110 and a side 122 of the base 120 brought into close proximity or into contact with the side 118 of the module 108. An interface may thereby be formed between the base 120 and the module 108 that extends between a front and rear side of the module 108 and between a front and rear side of the base 120 of the pin assembly 110. After inserting the pin terminal 112 into the base 120 and bringing the base 120 into contact with the module 108, the pin 140 may be inserted into the pin socket 135 and an end of the pin 140 inserted into the opening 116 of the pin terminal 112 to thereby connect the pin 140 to the pin terminal 112. In an example, the pin 140 provides an interlock that interlocks the base 120 to the module 108. In some examples, the mechanical coupling of the base 120 to the module 108 can be further enhanced through the addition of an adhesive or sealant at the interface to adhere or seal the side 122 of the base 120 to the side 118 of the module. In some examples, the side 122 and the side 118 may also include complementary recesses and protrusions that provide a mechanical interlocking between the base 120 and the module 108.

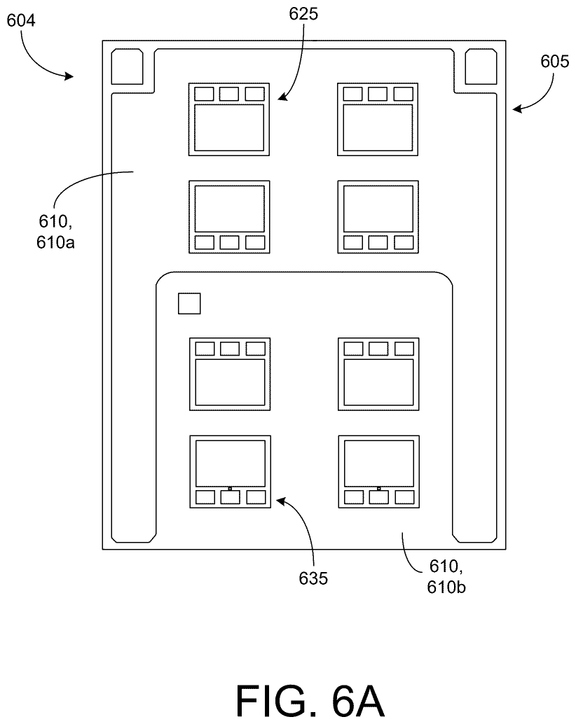

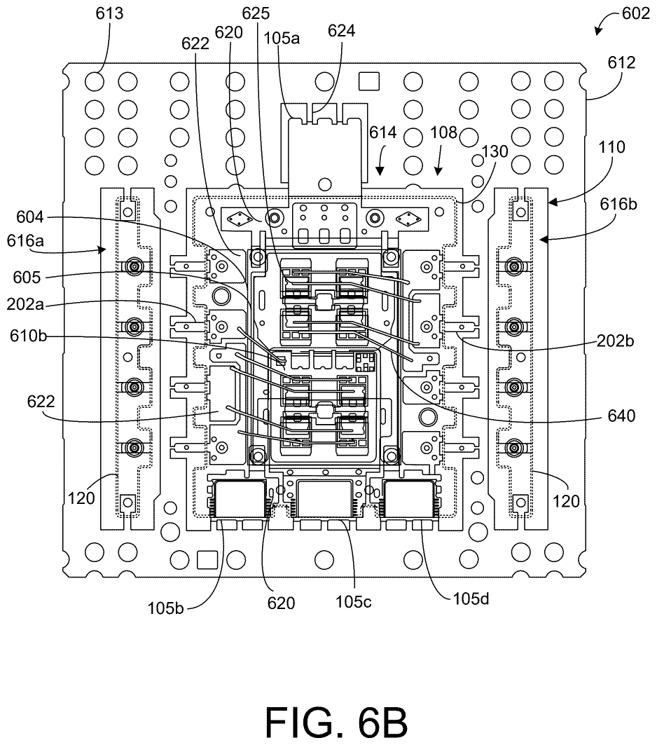

FIGS. 1B to 1D are diagrams illustrating, respectively, a front view, a first side view, and a bottom side view of an example semiconductor device assembly 100. Referring to FIGS. 1B-1D, the semiconductor device assembly 100 includes terminals 105a-105d, which can be included in a leadframe of the semiconductor device assembly 100, such as the example leadframe 602 shown in FIG. 6B. As described in further detail below, a leadframe of the semiconductor device assembly 100 can include a plurality of leadframe portions that respectively include the terminals 105a-105d.

Although referred to, by way of example, as a leadframe in at least some portions of this detailed description, a leadframe can include any type of conductive portion of a package or semiconductor device assembly (e.g., conductive portion, conductive terminal, etc.) that can provide an external connection point from an assembly to components, such as semiconductor die, within (e.g., encapsulated in) the assembly. Accordingly, the leadframe can be referred to as a conductive portion of the package. Furthermore, the semiconductor device assemblies described herein, as noted above, can include a plurality of terminals, such those noted above. The plurality of terminals can be power terminals, input signal terminals, output signal terminals, pins, and so forth. In some implementations, the plurality of terminals can be included in, coupled with, and/or attached to a leadframe, such as described herein.

In some implementations, one or more portions of a leadframe can be coupled to a pad (e.g., a bond pad) on at least a portion of a substrate, such as a direct-bonded metal (DBM) substrate (e.g., the substrate described below with respect to, at least, FIG. 6A). Briefly, however, as also shown in FIGS. 1B-1D, the semiconductor device assembly 100 includes a module 108 which may include a molding compound 130 formed from a molding compound or other encapsulant material. The module 108 may include a metal layer 125 that is exposed through the molding compound 130 on a rear side of the semiconductor device assembly 100. In some implementations, the metal layer 125 can be included in a substrate (e.g., a DBM substrate or other substrate) and used for attachment of the semiconductor device assembly 100 with a heat dissipation component, such as heat sink or fluidic cooling jacket. In an example, the molding compound 130 is an outer layer that encases one or more components of the semiconductor device assembly 100 including, for example, a substrate assembly 604 (FIG. 6A) and portions of a leadframe 602 (FIG. 6B).

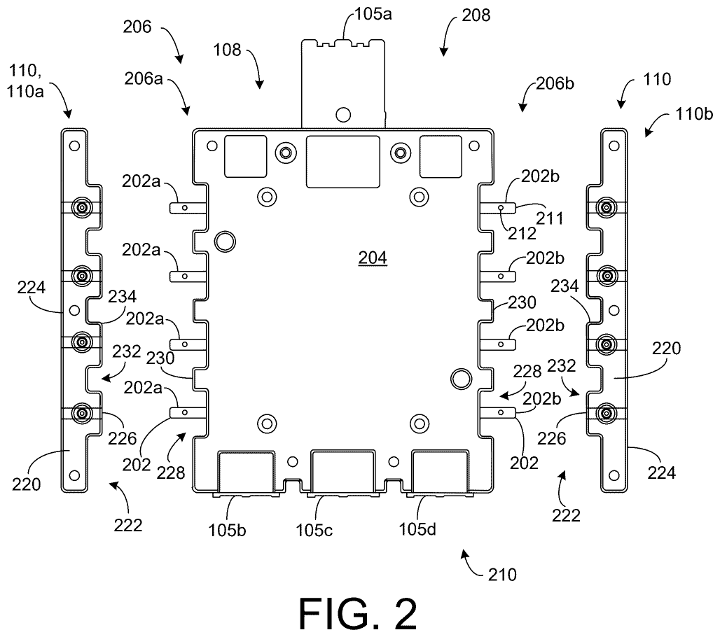

In the illustrated example, the semiconductor device assembly 100 is a press-fit pin package design in which a plurality of pins 140, e.g. press fit pins, extend vertically from the semiconductor device assembly 100. The semiconductor device assembly 100 may be configured to be coupled to a PCB of an electrical system at least in part by solderless press-fit pin connections via the pins 140. In the illustrated example, the semiconductor device assembly 100 includes one or more pin assemblies 110, e.g., a pin assembly 110a and a pin assembly 110b that are configured to be coupled to the module 108. In the illustrated example, the pin assemblies 110 each include a base 120 that may be formed from a molding compound. The base 120 may define a plurality of pin sockets 135. The plurality of pins 140 are respectively disposed in the plurality of pin sockets 135. In the illustrated example, semiconductor device assembly 100 includes four pin sockets 135 in each of the pin assemblies 110. In other examples, a pin assembly may include a greater or fewer pin sockets 135 and corresponding pins 140. As described herein, the modular nature of the pin assemblies 110 provides a number of benefits, including reduced manufacturing cost and complexity and increased design flexibility. For ease of illustration the base 120 of the pin assemblies 110 are shown as transparent to illustrate the plurality of pin terminals 202 and plurality of pin terminal openings 226 within the corresponding bases 120 (described below in connection with FIG. 2).

In some implementations, the molding compound 130 and/or base 120 may be formed from a molding material or compound, an encapsulation material, and the like and can be, or can include a non-conducting layer or material. In some implementations, the molding compound 130 and/or the base 120 is formed from a non-conducting material, such as an epoxy, which can be formed (applied, etc.) using a transfer molding process or a compression molding process in conjunction with corresponding tooling, e.g., a molding jig. In some implementations, the molding compound can include a separate plastic housing that is included in the semiconductor device assembly.

FIG. 1C illustrates a side view of the semiconductor device assembly 100, e.g., from a right side of the semiconductor device assembly 100 and FIG. 1D illustrates a bottom side view. As shown in FIGS. 1B and 1C, the pins 140 vertically extend out of, and away from a front side of the module 108 through the base 120. In some implementations, the portions of the pins 140 extended outside the base 120 can be inserted in a socket (or sockets) of a PCB of a corresponding electrical system, such as an inverter system for an electric or hybrid vehicle, or other electrical system. In some implementations, the pins 140 (as well as the terminals 105a-105d), can be plated, or partially plated, e.g., with a solder plating. Such plating can facilitate electrical attachment of the semiconductor device assembly 100 in a corresponding electrical system, e.g., using a solder reflow process.

FIG. 2 is a front side exploded view of the semiconductor device assembly 100 showing the pin assemblies 110 removed from the module 108 of the semiconductor device assembly 100. In an example, the pin assemblies 110 and module 108 can be fabricated as separate components and then coupled together to form the semiconductor device assembly 100.

As shown in FIG. 2, the module 108 includes a front side 204, opposing first side 206a and a second side 206b, and opposing top side 208 and bottom side 210. Terminal 105a extends in a first direction from the top side 208, and terminals 105b-105c extend in a second direction from the bottom side 210. Module 108 may also include a plurality of pin terminals 202 that may be coupled to a leadframe, such as pin conductors of the leadframe, and that are designed and configured to mechanically and electrically couple to corresponding ones of the pins 140. In an example, the pin terminals 202a extend in a third direction from the first side 206a and pin terminals 202b extend in a fourth direction from the second side 206b (pin terminals 202a and 202b may be individually or collectively referred to as pin terminal(s) 202). In an example the third and fourth directions are substantially parallel and are substantially perpendicular from the first and second directions. In an example, one or more of the pin terminals 202 have corresponding end 211 and a pin opening 212 (only one of each labeled in FIG. 2) that is designed and configured to receive a first end, or terminal end, of a pin, such as one of pins 140. In an example, an opening 212 on a given pin terminal is spaced from the corresponding side 206a or 206b of the module 108 by a distance such that the opening 212 will be aligned with a corresponding pin socket 135 and pin 140 of a pin assembly 110. Similarly, in an example, a pin socket 135 on a given pin assembly 110 is spaced from the corresponding side 222 of the pin assembly 110 by a distance such that the pin socket 135 will be aligned with an opening 212 of a corresponding pin terminal 202.

In an example, the pin assemblies 110 have a front side 220, and opposing first side 222 and second side 224, wherein the first side 222 is configured to engage one of the sides 206 of the module 108 of the semiconductor device assembly 100. The first side 222 includes a plurality of pin terminal openings 226 (only one on each pin assembly 110 labeled) that are designed and configured to slidingly receive corresponding ones of the plurality of pin terminals 202.

In an example, the sides 206a, 206b of the module 108 have a shape that is complementary to a shape of the first sides 222 of the pin assemblies 110 to facilitate engagement and coupling between the pin assemblies 110 and the module 108. In the illustrated example, the sides 206a, 206b include a plurality of recesses 228 and protrusions 230 (one of each on each side labeled). The first sides 222 of the pin assemblies 110 similarly include a plurality of recesses 232 and protrusions 234. The recesses 228 of the module 108 may have a shape and dimension that is complementary to a shape and dimension of the protrusions 234 of the pin assemblies 110. The protrusions 230 of the module 108 may have a shape and dimension that is complementary to a shape and dimension of the plurality of recesses 232 of the pin assemblies 110. In an example, the plurality of pin terminals 202 are located at a midpoint of a corresponding recess 228 and the plurality of pin terminal openings 226 are located at a midpoint of a corresponding recess 232 for alignment of the plurality of pin terminals 202 and plurality of pin terminal openings 226. In an example, a number of the plurality of recesses 228 in the module 108 may be the same as a number of the plurality of pin terminals 202 and number of the plurality of pin terminal openings 226 in the pin assemblies 110 may be the same as a number of the plurality of protrusions 234 in the pin assemblies 110.

Referring to FIGS. 1B-2, during an example assembly or manufacturing process, the pin terminals 202 can be inserted into corresponding pin terminal openings 226 of one of the bases 120 and the first side 222 of the base 120 brought into close proximity or into contact with the side 206 of the module 108. An interface 124 may thereby be formed between the base 120 and the module 108 that extends between the front side 204 and a rear side 150 of the module 108 and between the front side 220 and a rear side 152 of a corresponding base 120 of the pin assembly 110. In the illustrated example the front side 204 of the module 108 is substantially aligned with the front sides 220 of the bases 120, the rear side 150 of the module 108 is substantially aligned with the rear sides 152 of the bases 120, and a thickness of the module 108 at the sides 206 of the module 108 is substantially the same as thickness of the bases 120. In other examples the thickness of the one or more bases 120 may be different than other ones of the bases 120 and may be different than the thicknesses of the module 108. In some examples, the front side 204 of the module 108 may be offset from one or both of the front sides 220 of the bases 120. In some examples, the rear side 150 of the module 108 may be offset from one or both of the rear sides 152 of the bases 120.

After inserting the pin terminals 112 into a corresponding base 120 and bringing the base 120 into contact with the module 108, the pins 140 may be inserted into the pin socket 135 and an end of the pin 140 inserted into the opening 116 of the pin terminal 112 to thereby connect the pin 140 to the pin terminal 112. In an example, insertion or otherwise coupling or connecting the pin 140 with a pin terminal 112 acts as an interlock that locks the base 120 to the module 108. In some examples, the mechanical coupling of the base 120 to the module 108 can be further enhanced through the addition of an adhesive or sealant at the interface 124 to adhere the side 222 of the base 120 to the side 206 of the module 108. The adhesive or sealant may be applied to one or both of the first side 222 of the base 120 and/or the side 206 of the module 108 prior to bringing the first side 222 and the side 206 into contact. Alternatively or in addition, an adhesive or sealant may be applied at the interface 124 at the front side 204 of the module 108 front side 220 of the base 120 and/or the and a rear side 150 of the module 108 and rear side 152 of the base 120 after coupling the base 120 to the module 108.

Semiconductor device assembly 100 is provided by way of example. In some examples, a number of the plurality of pin terminals 202 and a number of the plurality of pin terminal openings 226 may vary from the number shown. In an example, the shape of the sides 206a, 206b of the module 108 and the shape of the first sides 222 of the pin assemblies 110 or the number and location of the pin terminals and pin terminal openings with respect to the recesses and protrusions may be different from the illustrated example. For example, the module 108 may define protrusions that include pin terminals extending therefrom (rather than or in addition to pin terminals extending the recesses 228) and the pin assemblies 110 may define recesses that include pin terminal openings (rather than or in addition to pin terminal openings in protrusions) that are configured to engage the protrusions of the module 108. In some examples, shapes other than square or rectangular recesses and protrusions, such as triangular or other polygon may be used. In some examples, pin terminals may extend from both recesses and protrusions of a body of a semiconductor device assembly. In some examples, two or more pin terminals may extend from a corresponding recess or protrusion. In some examples, pin terminal openings may be located in both recesses and protrusions of a pin assembly. In some examples, two or more pin terminal openings may be located in a corresponding recess or protrusion.

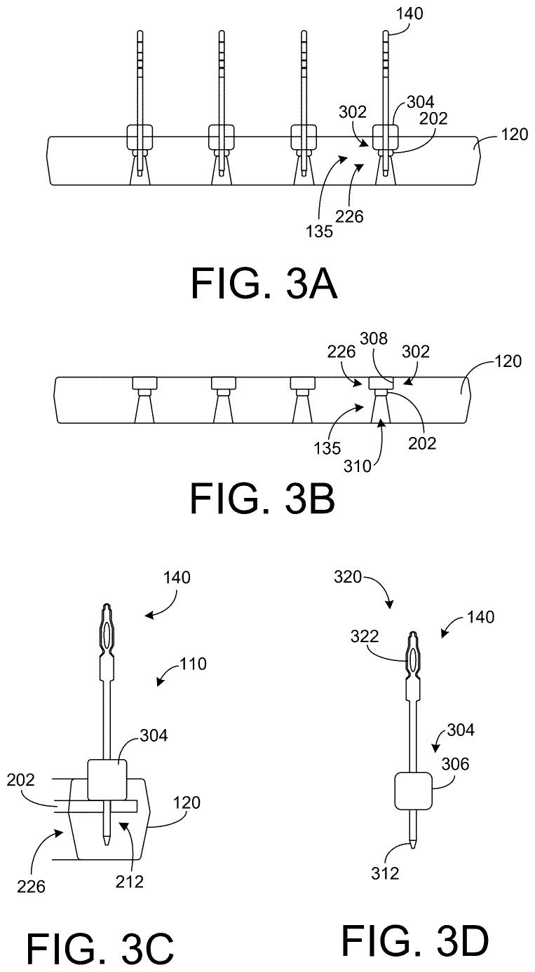

FIG. 3A is a cross-sectional side view of semiconductor device assembly 100 taken along section line 3-3 of FIG. 1B. FIG. 3B is a cross-sectional view of the semiconductor device assembly 100 taken along section line 3-3 of FIG. 1B with the pins 140 removed. FIG. 3C is an end section view showing one of the pins 140 in an inserted position and coupled to a pin terminal 202, and FIG. 3D shows one of the pins 140. Referring to FIGS. 3A-3D, in the illustrated example the base 120 of the pin assembly 110 defines the plurality of pin sockets 135 that the pins 140 are disposed in. In an example, the plurality of pin sockets 135 each extend through a thickness of the base 120. The pin sockets 135 intersect corresponding ones of the plurality of pin terminal openings 226 in the base 120 (see also FIG. 2) for receipt of the pin terminals 202.

The pins 140 may each include a non-conductive body 304 that is molded to the pin 140 and that may be formed from a molding compound, which may be, for example, a thermoplastic or thermoset, such as Polybutylene Terephthalate (PBT) or an epoxy molding compound (EMC). In an example, the non-conductive body 304 may have a shape and dimension that is complementary to a shape and dimension of first portions 302 of the plurality of pin sockets 135 such that the non-conductive body 304 can be slidably disposed into a corresponding pin socket 135. An outer wall 306 of the non-conductive body 304 may be configured to engage an inner wall 308 of a corresponding first portion 302 of one of the pin sockets 135 to thereby provide a supportive base for the pin 140 in the base 120 and for coupling the pin 140 to the base 120. The pin sockets 135 may also include a second portion 310, which in an example may be a flared portion, in which a first end portion 312, also referred to herein as a terminal end, of a corresponding pin 140 is configured to be disposed.

As shown in, for example, FIG. 3C, in an assembled configuration, the first end portions 312 of the pins 140 are configured to be inserted into corresponding ones of the openings 212 in the pin terminals 202 to thereby effectively lock the pin assemblies 110 in engagement with the module 108 of the semiconductor device assembly 100. In an example, a size or shape of the first end portion 312 of the pin 140 may be designed and configured for an interference fit and/or to deform the opening 212 pin terminal 202. For example, a size of the first end portion 312 may be greater than a size of the opening 212. For example, a cross-sectional shape of the first end portion 312 may be different than a shape of the opening 212. By way of example, the first end portion 312 may have a square cross-sectional shape and the opening 212 may have a round cross-sectional shape.

During an assembly process, the bases 120 of the pin assemblies 110 may first be coupled to the module 108 by inserting the plurality of pin terminals 202 into corresponding pin terminal openings 226 and pressed into engagement until the plurality of recesses 228 and protrusions 230 of the module 108 are engaged with and inserted into the plurality of recesses 232 and protrusions 234 of a base 120 of the pin assembly 110 (see FIG. 2). After engaging the base 120 with the module 108, the pins 140 can then be inserted into corresponding pin sockets 135 and the first end portions 312 of the pins inserted into the openings 212 of the plurality of pin terminals 202 to mechanically and electrically couple the pins 140 to the leadframe 602 of the module 108.

In the illustrated example the pins 140 are press-fit pins and include a press-fit end 320 that includes a deformable press-fit eye 322 that is configured to be inserted into an opening of a PCB. In other examples, pin assemblies 110 of the present disclosure may include solder pins in addition to or instead of press-fit pins.

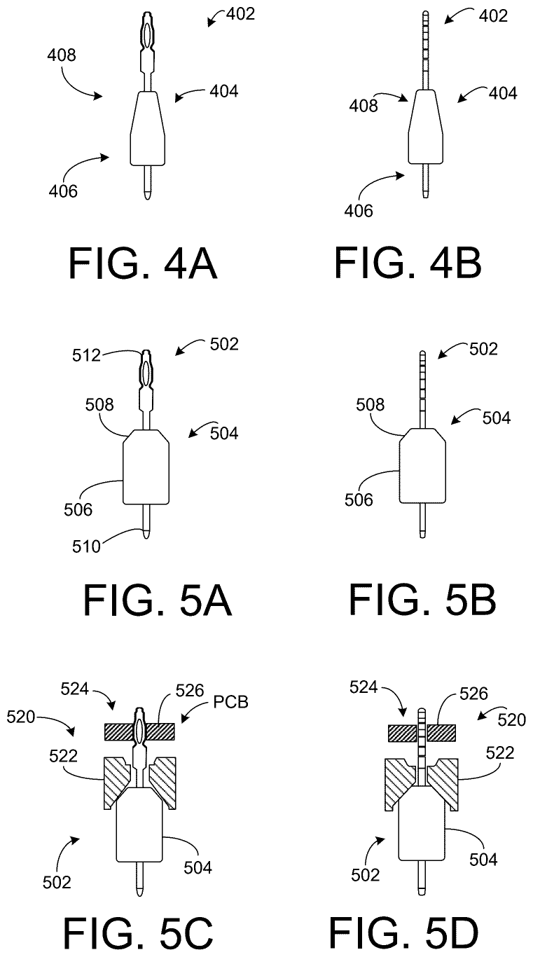

FIG. 4A is a front view of a pin 402 and FIG. 4B is a side view of the pin 402. Pin 402 is a press-fit pin and includes a non-conductive body 404 that is configured to be disposed in a pin socket of a pin assembly, such as one of pin sockets 135 of pin assembly 110. As with non-conductive body 304 of pin 140 (see, e.g., FIG. 3D), non-conductive body 404 includes a first end 406 that has a shape and dimension that is complementary to a shape and dimension of a pin socket of a base of a pin assembly, such as one of pin sockets 135 of base 120. Non-conductive body 404 also has a second end 408 that is configured to engage a pin guide of a socket of an electrical system, such as an inverter system, that the semiconductor device assembly 100 is configured to be coupled to. In the illustrated example the second end 408 of the non-conductive body 404 has a tapered shape for guiding the pin 402 into a socket.

FIG. 5A is a front view of a pin 502 and FIG. 5B is a side view of the pin 502. FIG. 5C is a section front view of the pin 502 inserted into a socket 520 of an electrical system such as an inverter system, and FIG. 5D is a section side view of the pin 502 inserted into the socket 520. Referring to FIGS. 5A-5D, in the illustrated example, the pin 502 includes a non-conductive body 504 that is configured to be disposed in a pin socket of a pin assembly, such as one of pin sockets 135 of pin assembly 110. Pin 502 has a first end 510 or terminal end that is configured to be coupled to a terminal of a semiconductor device assembly 100 such as one of pin terminals 202. Pin 502 has a second end 512, or press-fit end, that includes a deformable press-fit eye configured to be press-fit into an opening 524 of a PCB 526 of a socket 520.

As with non-conductive body 404 of pin 402 (FIG. 4A, 4B) the non-conductive body 504 includes a first end 506 that has a shape and dimension that is complementary to a shape and dimension of a socket of a pin assembly, such as one of pin sockets 135 of pin assembly 110. Non-conductive body 504 also has a second end 508 that is configured to engage a pin guide 522 of the socket 520 of an electrical system, such as an inverter system. In the illustrated example the second end 508 of the non-conductive body 504 has a tapered shape for guiding the pin 502 into the socket 520. As shown in FIGS. 5C and 5D, the second end 508 has a shape and dimension that is complementary to a shape and dimension of the pin guide 522.

In an example, the non-conductive body 504 may be designed and configured as a multi-functional component that provides one or more functions. For example, the non-conductive body 504 may provide the function of a base that couples the pin 502 to a base of a pin assembly such as base 120 (see e.g. FIG. 3A) and supports the pin in the base. The non-conductive body 504 may also be designed and configured to function as a guide member for guiding the pin 502 into the socket 520. The non-conductive body 504 may also be designed and configured to function as a structural member that structurally supports the pin 502 when the semiconductor device assembly is coupled to PCB 526. For example, the non-conductive body 504 may have a length that is designed and configured to extend from the pin guide 522 to the base 120 when the semiconductor device assembly 100 is coupled to the PCB 526 and act as a structural support member for the portion of the pin 502 extending between the base 120 and the pin guide 522.

Referring again to FIGS. 4A and 4B, non-conductive body 404 may similarly be designed and configured as a multi-functional component. Non-conductive body 404 and non-conductive body 504 are two non-limiting examples and illustrate an ability to customize the semiconductor device assembly 100 for a given application. For example, the pin assemblies 110 may be customizable such that the same module 108 may be used for a variety of different electrical systems requiring a different number and position of pins and having differently shaped and dimensioned sockets. The body portion of the pin, such as non-conductive body 304, non-conductive body 404, or non-conductive body 504 may be customized to a given application such that a shape or dimension may be varied according to an application.

FIG. 6A illustrates an example substrate assembly 604 that may be implemented in module 108 of semiconductor device assembly 100. FIG. 6B illustrates the semiconductor device assembly 100 prior to application of a molding compound to the module 108 and pin assemblies 110 by, e.g., an injection molding process. The dotted lines in FIG. 6B indicate for reference purposes the outer perimeter of the molding compound of molding compound 130 and base 120 after the molding process is performed.

Referring to FIGS. 6A and 6B, in the illustrated example, the module 108 and pin assemblies 110 may be formed from a common leadframe 602 component, which can simplify manufacturing and reduce manufacturing costs as compared to manufacturing them separately. In other examples, the module 108 and pin assemblies 110 may be formed separately. FIG. 6A shows an example substrate assembly 604 that may include a substrate 605, which can be a DBM substrate and a plurality of semiconductor die 625 (only one labeled) and a plurality of semiconductor die 635 (only one labeled) that are coupled (electrically coupled, physically coupled) to the substrate 605.

In some implementations, a direct bonded metal (DBM) substrate can include an insulating layer disposed between a first metal layer and a second metal layer. The insulating layer can be, for example, a ceramic layer. In some implementations, the insulating layer can be, or can include, for example, a ceramic material such as alumina (Al₂O₃) or aluminum nitride (AlN)). In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process and/or a lamination process. In some implementations, the first metal layer and/or the second metal layer of the DBM substrate can be, or can function as, a heat sink. In some implementations, the first metal layer and/or the second metal layer (such as the metal layer 125 of the semiconductor device assembly 100) can be coupled to a heat sink or other heat dissipation component. In some implementations, at least a portion of one or more of the first metal layer or the second metal layer can be exposed through a molding material, such as shown in FIG. 1B.

In some implementations, the first metal layer and/or the second metal layer of the DBM substrate can be or can include a patterned metal layer including one or more electrically conductive traces. In some implementations, the first metal layer and/or the second metal layer can be, or can include a patterned layer configured to form one or more electrical circuits, one or more patterned metal layers or metal layer portions, one or more conductive blind and/or through vias, and/or so forth.

In some implementations, the DBM substrate can be, or can include a direct bonded copper (DBC) substrate (e.g., a DBM with copper metal layers). In some implementations, such as in DBC substrate implementations, the first metal layer and/or the second metal layer is a copper layer.

For instance, in the example of FIG. 6A, the substrate 605 includes at least one metal layer 610a (e.g., at least one first patterned metal layer or metal layer portion) and a metal layer 610b (e.g., a second patterned metal layer or metal layer portion). In this example, the metal layer 125 shown in FIG. 1B can be disposed on an opposite side of the substrate 605 as shown in FIGS. 1B and 1C (e.g., on an opposite side of an insulating layer of the substrate 605).

As shown in FIG. 6A, the substrate assembly 604 includes a plurality of semiconductor die 625 (only one labeled) that are coupled (electrically coupled, physically coupled) with the at least one metal layer 610a. The substrate assembly 604 also includes a plurality of semiconductor die 635 that are coupled (electrically coupled, physically coupled) with the metal layer 610b. In some implementations, the plurality of semiconductor die 625 and 635 can be coupled with their respective metal layers using a number of different processes, such as soldering processes, or sintering processes.

In some implementations, soldering can be or can include a process of joining two surfaces (e.g., metal surfaces and semiconductor surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal or metal-to-semiconductor type bonding materials.

In some implementations, a coupling of components can be performed using, for example, a solder process, a sintering process (e.g., a silver sintering process, a copper sintering process), and/or other metal-to-metal or metal-to-semiconductor bonding processes.

By way of example, and for purposes of illustration, the plurality of semiconductor die 625 and the plurality of semiconductor die 635 can include respective SiC power transistors (e.g., MOSFET transistors) that may be used to implement a high-side switch of a half-bridge circuit (with the respective transistors being connected in parallel) and a low-side switch of a half-bridge circuit (with the respective transistors being connected in parallel). In some implementations, other circuits can be implemented and/or combinations of transistors can be included in the substrate assembly 604.

For instance, in some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRD), a diode, and/or so forth. In some implementations, one or more semiconductor die can be (e.g., can be a portion of), or can include a component for an electrical vehicle (EV).

More than one semiconductor die can be included in the implementations described herein, as in the substrate assembly 604. In some implementations, different semiconductor die (when more than one semiconductor die is included) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT or MOSFET can be fabricated using a SiC substrate, while a controller can be fabricated using a silicon substrate.

In example implementations, a first semiconductor die can be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may also be connected to leadframe posts, leadframe portions, and/or leadframe terminals by electrical connections such as wire bonds or conductive clips.

Referring to FIG. 6B, in the illustrated example, the leadframe 602 includes an outer frame 612 that is removed during a trim process and after a molding process. The outer frame 612 may include a plurality of alignment features 613 (only one labeled) such as openings in the leadframe for performing an alignment process during manufacturing. Leadframe 602 also includes a module portion 614 that includes leadframe components of the module 108 and pin assembly portions 616a, 616b where the bases 120 of the pin assemblies 110 are formed.

The module portion 614 of the leadframe 602 includes a plurality of leadframe portions 620 (only two labeled) for connecting the substrate assembly 604 to external components. The terminals 105a-105d are also included in the plurality of leadframe portions 620. The module portion 614 also includes a plurality of pin conductors 622 (only two labeled) for connecting to the pins 140 via the plurality of pin terminals 202. The various components of the leadframe 602 may be connected using tie bars 624 (one labeled), where the tie bars are removed as part of a trim operation performed during a manufacturing process used to produce a semiconductor device assembly, e.g., the semiconductor device assembly 100. For instance, such tie bars can maintain a relative arrangement of the components of the leadframe 602 during the assembly manufacturing process.

The leadframe 602 may be coupled (stacked, vertically stacked) with the substrate assembly 604 using approaches described herein, such as soldering and/or sintering. In addition to electrically coupling one or more parts of the leadframe 602 with the substrate assembly 604, one or more other parts of the leadframe 602 may be coupled with the substrate assembly 604 without establishing an electrical connection to the substrate assembly 604.

In an example, the terminal 105c of the leadframe 602 implements a negative power supply terminal (e.g., DC-, electrical ground, etc.) of a half-bridge circuit, and the terminals 105b and 105d implement power supply terminals (DC+, Vcc, etc.) of the half-bridge circuit. The terminal 105b and the terminal 105d may be coupled, physically and electrically) with the metal layer 610a, which provides electrical connection from the terminal 105b and the terminal 105d to respective drain terminals of the high-side transistors of the half-bridge circuit (e.g., of the plurality of semiconductor die 625). Terminal 105a may implement an output AC terminal.

FIG. 6B also shows wire bonds (e.g., attached bond wires 640 (only one labeled)). The bond wires 640 may electrically couple the module portion 614 of the leadframe 602 with the plurality of semiconductor die 625, the plurality of semiconductor die 635, or other components of the assembly.

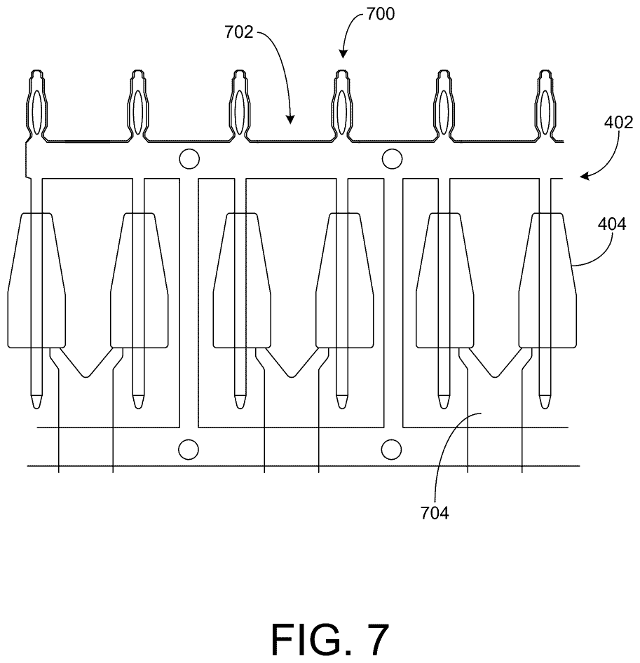

FIG. 7 shows an example of a transfer molding press-fit pin frame assembly 700, also referred to herein as a pin frame assembly, which includes a plurality of the pins 402 (see also FIGS. 4A, 4B) coupled to a frame 702. The pin frame assembly 700 can be used to efficiently manufacture multiple pins such as the pins disclosed herein. For example, the pin frame assembly 700 can be used to manufacture a plurality of pre-molded press fit pins, such as pins 402, which may then be separated or trimmed from the frame 702 and inserted into the base 120 to form the pin assembly 110.

The frame 702 may include gates 704, for example, epoxy mold compound (EMC) gates, for use in a transfer molding process to form the non-conductive body 404 of the pins 402. A pin frame assembly such as pin frame assembly 700 can provide the benefit of customization so that the semiconductor device assembly 100 can be tailored for a given electrical system. For example, the frame 702 and gates 704 along with the transfer molding system, can be varied to adjust a size and shape of the non-conductive body, such as non-conductive body 404 to conform with the shape and dimensions of a given electrical system, thereby allowing the semiconductor device assembly 100 to be readily compatible with different systems having different pin interface designs.

The modular nature of the pin assemblies of the present disclosure provides a new degree of freedom or flexibility in the design and configuration of the number and location of pins which can facilitate the configuration of a semiconductor device assembly for a given application. For example, a number and location of the pins of a semiconductor device assembly of the present disclosure can vary, as well as a size of the pin assembly and the sides of the module where the pin assemblies are attached. For example, semiconductor device assembly 100 includes two pin assemblies 110 which are coupled to the opposing sides 206a, 206b of the module 108. In other examples, semiconductor device assemblies of the present disclosure may include pin assemblies coupled to additional or other portions of a module. For example, in addition to or instead of being coupled to opposing left and right sides 206a, 206b of the module, a pin assembly may be coupled to the top side 208 or bottom side 210 or coupled to the front side 204.

In one example the pin assemblies 110 have a rail shape and include a linear array of the pins 140. In other examples, pin assemblies of the present disclosure may have other shapes and may have varying numbers of pins located on the base of a pin assembly in different locations and with different pin-to-pin spacing. For example, a pin-to-pin spacing may be greater or less than semiconductor device assembly 100, the pin-to-pin spacing may vary across the pin assembly, a pattern of the pins may be different than linear, such as arranged in a square, rectangular, or other pattern, and the number of pins in a pin assembly may be different.

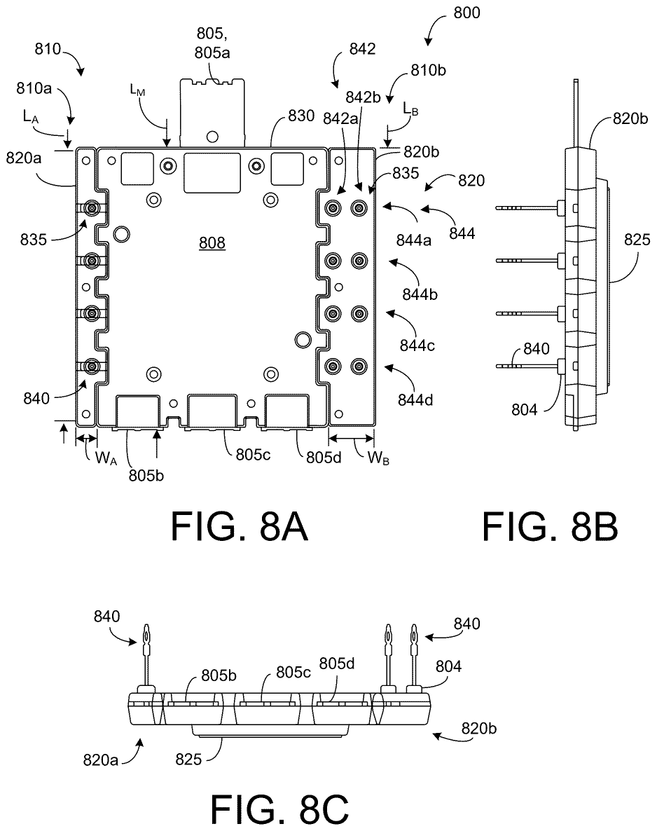

FIGS. 8A-10D illustrate example implementations of semiconductor device assemblies with varying numbers and positions of pins. The illustrated examples are merely provided by way of example.

FIGS. 8A-8C show one example of a semiconductor device assembly 800 that includes pin assemblies 810a, 810b having a different pin arrangement than semiconductor device assembly 100. For example a number of columns of pins can be varied and the number of columns of pins in the two or more pin assemblies may be different. FIG. 8A is a front view of semiconductor device assembly 800, FIG. 8B is a right side view of the semiconductor device assembly 800 and FIG. 8C is a bottom side view of the semiconductor device assembly 800. Referring to FIGS. 8A-8C, the semiconductor device assembly 800 has a similar configuration to semiconductor device assembly 100 (FIG. 1B-1D) and includes terminals 805a, 805b, 805c, 805d, which can be included in a leadframe of the semiconductor device assembly 800. The leadframe may be coupled to a pad (e.g., a bond pad) on at least a portion of a substrate, such as a direct-bonded metal (DBM) substrate, which may include a metal layer 825. Semiconductor device assembly 800 includes a module 808 which may include a molding compound layer 830 formed from a molding compound or other encapsulant material. The metal layer 825 of a DBM substrate may be exposed through the molding compound layer 830 and used for attachment of the semiconductor device assembly 800 to a heat dissipation component, such as heat sink or fluidic cooling jacket.

In the illustrated example, the semiconductor device assembly 800 is a press-fit pin package design in which a plurality of pins 840, e.g. press-fit pins, extend vertically from the semiconductor device assembly 800. The semiconductor device assembly 800 may be configured to be coupled to a PCB of an electrical system at least in part by solderless press-fit pin connections via the pins 840. In the illustrated example, the semiconductor device assembly 800 includes one or more pin assemblies 810, e.g., pin assemblies 810a and 810b, that are configured to be coupled to the module 808. As with the semiconductor device assembly 100 (FIG. 1B-1D), the pin assemblies 810 are configured to be removably coupled to the module 808 by inserting pin terminals (not illustrated) into corresponding pin terminal openings of the base 820 of the pin assembly 810. Also, as with the semiconductor device assembly 100, the sides of the module 808 may have a series of recesses and protrusions and a side of the pin assemblies 810 may have a mating set of recesses and protrusions for engagement therebetween to facilitate a secure alignment and a secure engagement between the module 808 and the pin assemblies 810.

In the illustrated example, the pin assemblies 810 include a corresponding base 820a, 820b that may be formed from a molding compound. The bases 820 may define a plurality of pin sockets 835 (one on each base labeled). The plurality of pins 840 are respectively disposed in the plurality of pin sockets 835. In an example, one or more of the pins 840 may include a corresponding non-conductive body 804 which may be disposed, e.g., inserted into, a corresponding pin socket 835.

Unlike semiconductor device assembly 100, which includes two pin assemblies 110 having substantially the same configuration and number of pins 140, pin assemblies 810a 810b have different configurations. The configuration of pin assembly 810a is similar to pin assembly 110a and includes a linear array or column of pins 840 and a substantially equal pin-to-pin spacing or pitch. Pin assembly 810b includes two columns 842a, 842b or linear arrays of pins 840 and the pins in the two columns are substantially aligned in corresponding rows 844a, 844b, 844c, 844d, 844d. In other examples, a pin assembly of the present disclosure may have three or more columns of pins 840.

A pin-to-pin spacing or pitch of the pins 840 in pin assembly 810b may be substantially the same. In one example, the pins 840 in a given row 844 of pin assembly 810b may be coupled to a common pin terminal (not illustrated) of a leadframe of the semiconductor device assembly 800. Thus, in the illustrated example, pin assembly 810b includes four pairs of pins 840 located in corresponding rows 844 and each pair is coupled to a common pin terminal. In an example, a current capability for a given pin terminal coupled to two pins may be greater than a current capability for a pin terminal coupled to one pin. For example a current capability for a pin terminal and corresponding lead terminal coupled to two pins 840 may be in a range of approximately 40 A to approximately 50 A as compared to approximately 20 A to approximately 25 A for a pin terminal coupled to one pin.

The pin assemblies 810a, 810b have a corresponding width, Wa, Wb, and length, La, Lb. The lengths La, Lb of the pin assemblies 810 are substantially the same, and the lengths may be substantially the same as a length, Lm, of module 808. In an example the width, Wb, of pin assembly 810b is greater than the width, Wa, of pin assembly 810a to accommodate the additional column 842 of pins 840. For example, a size of the base of a pin assembly, such as one of bases 820 of pin assemblies 810, can be varied to account for a number and spatial pattern of the pins disposed in the base, such as pins 840, that may be needed for a given application. In the illustrated example, semiconductor device assembly 800 is designed and configured to couple to an electrical system that requires two columns of pins 840 on one side of the module 808 and one column of pins 840 on the other side of the module. Base 820b has a greater width, Wb, than base 820a to accommodate the additional column of pins 840.

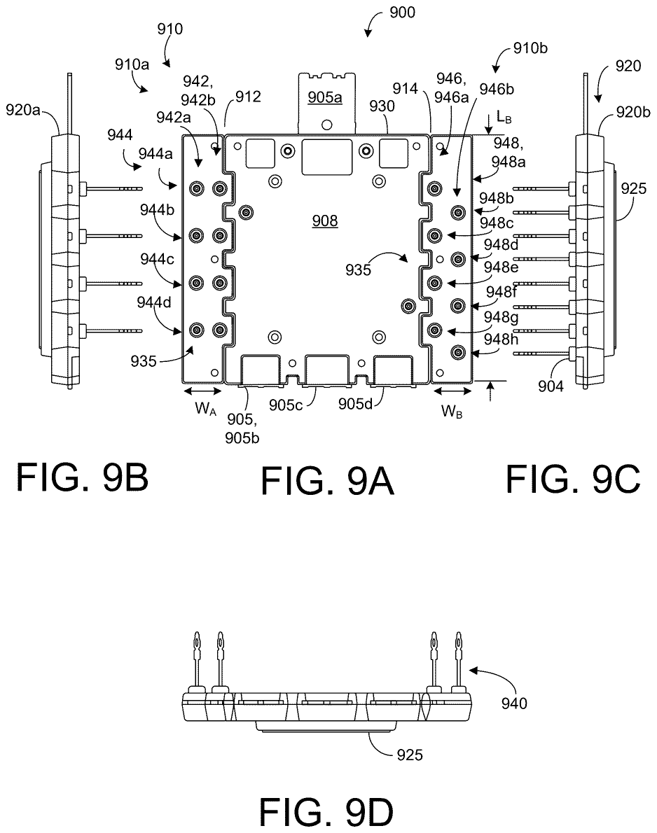

FIGS. 9A-9D show one example of a semiconductor device assembly 900 that includes pin assemblies 910 having a different pin arrangement than semiconductor device assembly 100. For example, a number of and spacing of pins may vary between the columns of pins and the columns of pins may be staggered. FIG. 9A is a front view of semiconductor device assembly 900, FIG. 9B is a left side view of the semiconductor device assembly 900, FIG. 9C is a right side view of semiconductor device assembly 900, and FIG. 9D is a bottom side view of the semiconductor device assembly 900. (FIG. 9B shows pins 940 coupled to pin assembly 910a and for clarity of illustration omits the pins coupled to pin assembly 910b. FIG. 9C shows pins 940 coupled to pin assembly 910b and for clarity of illustration omits the pins coupled to pin assembly 910a).

Referring to FIGS. 9A-9D, the semiconductor device assembly 900 has a similar configuration to semiconductor device assembly 100 (FIG. 1B-1D) and includes terminals 905a, 905b, 905c, 905d, which can be included in a leadframe of the semiconductor device assembly 900. The leadframe may be coupled to a pad (e.g., a bond pad) on at least a portion of a substrate, such as a direct-bonded metal (DBM) substrate, which may include a metal layer 925. Semiconductor device assembly 900 includes a module 908 which may include a molding compound layer 930 formed from a molding compound or other encapsulant material. The metal layer 925 of a DBM substrate may be exposed through the molding compound layer 930 and used for attachment of the semiconductor device assembly 900 to a heat dissipation component, such as heat sink or fluidic cooling jacket.

In the illustrated example, the semiconductor device assembly 900 is a press-fit pin package design in which a plurality of pins 940, e.g. press-fit pins, extend vertically from the semiconductor device assembly 900. The semiconductor device assembly 900 may be configured to be coupled to a PCB of an electrical system at least in part by solderless press-fit pin connections via the pins 940. In the illustrated example, the semiconductor device assembly 900 includes one or more pin assemblies 910, e.g., pin assemblies 910a and 910b, that are configured to be coupled to the module 908. As with the semiconductor device assembly 100 (FIG. 1B-1D), the pin assemblies 910 are configured to be removably coupled to the module 908 by inserting pin terminals (not illustrated) into corresponding pin terminal openings of the base 920 of the pin assembly 910. Pin assembly 910a is coupled to a left side 912 of module 908 and pin assembly 910b is coupled to a right side 914 of the module 908. Also, as with the semiconductor device assembly 100, the sides of the module 908 may have a series of recesses and protrusions and a side of the pin assemblies 910 may have a mating set of recesses and protrusions for engagement therebetween to facilitate a secure alignment and a secure engagement between the module 908 and the pin assemblies 910.

In the illustrated example, the pin assemblies 910a, 910b include a corresponding base 920a, 920b that may be formed from a molding compound. The bases 920 may define a plurality of pin sockets 935 (one on each base labeled). The plurality of pins 940 are respectively disposed in the plurality of pin sockets 935. In an example, one or more of the pins 940 may include a corresponding non-conductive body 904 which may be disposed, e.g., inserted into, a corresponding pin socket 935.

Unlike semiconductor device assembly 100, which includes two pin assemblies 110 having substantially the same configuration and number of pins 140, pin assemblies 910a 910b have different configurations. The configuration of pin assembly 910a is similar to pin assembly 810b of semiconductor device assembly 800 (FIG. 8A) two columns 942a, 942b or linear arrays of pins 940 and the pins in the two columns are substantially aligned in corresponding rows 944a, 944b, 944c, 944d. A pin-to-pin spacing or pitch of the pins 940 in pin assembly 910a may be substantially the same. In one example, the pins 940 in a given row 944 of pin assembly 910a may be coupled to a common pin terminal (not illustrated) of a leadframe of the semiconductor device assembly 900. Thus, in the illustrated example, pin assembly 910a includes four pairs of pins 940 located in corresponding rows 944 and each pair is coupled to a common pin terminal.

As with pin assembly 910a, pin assembly 910b includes two columns 946a, 946b of pins 940. Unlike pin assembly 910a, the columns of pin assembly 910b are staggered or offset, resulting in eight rows 948a, 948b, 948c, 948d, 948e, 948f, 948g, 948h of pins 940, and only one pin in each row, and each of the pins may be coupled to a different corresponding pin terminal (not illustrated). A leadframe of semiconductor device assembly 900 may, therefore, have a greater number of pin terminals on the right side 914 of the module 908 than the left side 912 and base 920b may have a greater number of pin terminal openings than base 920a.

The pin assemblies 910a, 910b have a corresponding width, Wa, Wb, and length, La, Lb. The lengths La, Lb of the pin assemblies 910 are substantially the same, and the lengths may be substantially the same as a length, Lm, of module 908. In an example the width, Wb, of pin assembly 910b is substantially the same as the width, Wa, of pin assembly 910a.

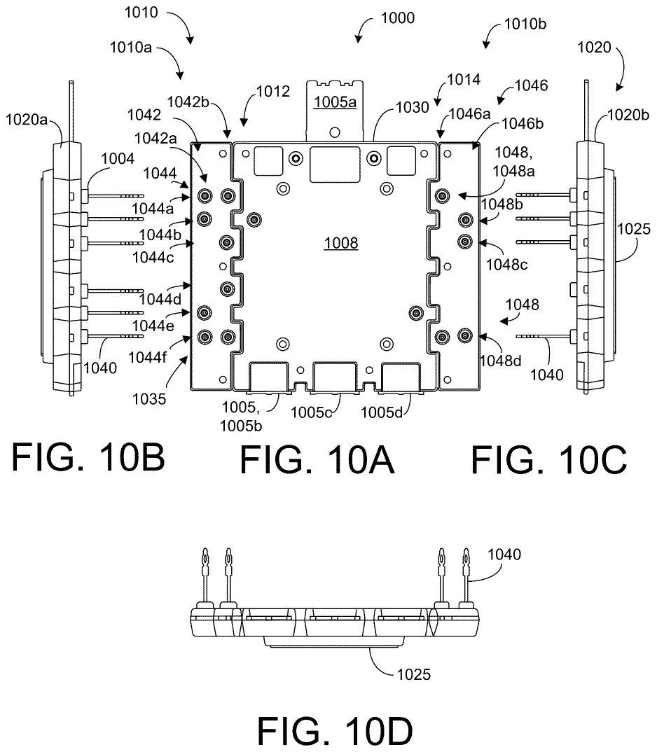

FIGS. 10A-10D show one example of a semiconductor device assembly 1000 that includes pin assemblies 1010 having a different pin arrangement than semiconductor device assembly 100. For example, a number of and spacing of pins may vary between the columns of pins and the columns of pins may be staggered. FIG. 10A is a front view of semiconductor device assembly 1000, FIG. 10B is a left side view of the semiconductor device assembly 1000, FIG. 10C is a right side view of semiconductor device assembly 1000, and FIG. 10D is a bottom side view of the semiconductor device assembly 1000. (FIG. 10B shows pins 1040 coupled to pin assembly 1010a and for clarity of illustration omits the pins coupled to pin assembly 1010b. FIG. 10C shows pins 1040 coupled to pin assembly 1010b and for clarity of illustration omits the pins coupled to pin assembly 1010a).

Referring to FIGS. 10A-10D, the semiconductor device assembly 1000 has a similar configuration to semiconductor device assembly 100 (FIG. 1B-1D) and includes terminals 1005a, 1005b, 1005c, 1005d, which can be included in a leadframe of the semiconductor device assembly 1000. The leadframe may be coupled to a pad (e.g., a bond pad) on at least a portion of a substrate, such as a direct-bonded metal (DBM) substrate, which may include a metal layer 1025. Semiconductor device assembly 1000 includes a module 1008 which may include a molding compound layer 1030 formed from a molding compound or other encapsulant material. The metal layer 1025 of a DBM substrate may be exposed through the molding compound layer 1030 and used for attachment of the semiconductor device assembly 1000 to a heat dissipation component, such as heat sink or fluidic cooling jacket.

In the illustrated example, the semiconductor device assembly 1000 is a press-fit pin package design in which a plurality of pins 1040, e.g. press-fit pins, extend vertically from the semiconductor device assembly 1000. The semiconductor device assembly 1000 may be configured to be coupled to a PCB of an electrical system at least in part by solderless press-fit pin connections via the pins 1040. In the illustrated example, the semiconductor device assembly 1000 includes one or more pin assemblies 1010, e.g., pin assemblies 1010a and 1010b, that are configured to be coupled to the module 1008. As with the semiconductor device assembly 100 (FIG. 1B-1D), the pin assemblies 1010 are configured to be removably coupled to the module 1008 by inserting pin terminals (not illustrated) into corresponding pin terminal openings of the base 1020 of the pin assembly 1010. Pin assembly 1010a is coupled to a left side 1012 of module 1008 and pin assembly 1010b is coupled to a right side 1014 of the module 1008. Also, as with the semiconductor device assembly 100, the sides of the module 1008 may have a series of recesses and protrusions and a side of the pin assemblies 1010 may have a mating set of recesses and protrusions for engagement therebetween to facilitate a secure alignment and a secure engagement between the module 1008 and the pin assemblies 1010.

In the illustrated example, the pin assemblies 1010a, 1010b include a corresponding base 1020a, 1020b that may be formed from a molding compound. The bases 1020 may define a plurality of pin sockets 1035 (one on each base labeled). The plurality of pins 1040 are respectively disposed in the plurality of pin sockets 1035. In an example, one or more of the pins 1040 may include a corresponding non-conductive body 1004 which may be disposed, e.g., inserted into, a corresponding pin socket 1035.

Unlike semiconductor device assembly 100, which includes two pin assemblies 110 having substantially the same configuration and number of pins 140, pin assemblies 1010a 1010b have different configurations. Pin assembly 1010a includes two columns 1042a, 1042b or linear arrays of pins 1040, where a number and spacing of the pins 1040 of the two columns 1042 is different. Pin assembly 1010a includes six rows 1044a, 1044b, 1044c, 1044d, 1044e, 1044f of pins 1040. Some of the rows 1044 have two pins 1040 (e.g. rows 1044a and 1044f) and other rows 1044 have only one pin (e.g. rows 1044b-1044e). A pin-to-pin spacing or pitch of the pins 1040 in column 1042a is varied while the spacing is substantially the same for column 1042b. The pins 1040 in rows 1044a and 1044f may be coupled to a common pin terminal, while the pins 1040 in rows 1044b-1044e may each be coupled to a different pin terminal.

Pin assembly 1010b may similarly include two columns 1046a, 1046b or linear arrays of pins 1040, where a number and spacing of the pins 1040 of the two columns 1046 is different. Pin assembly 1010b includes four rows 1048a, 1048b, 1048c, 1048d of pins 1040. One row, e.g., row 1048d includes two pins 1040 while rows 1048a-1048c each include only one pin. A pin-to-pin spacing or pitch of the pins 1040 in both columns 1046a and 1046b is varied. The pins 1040 in row 1048d may be coupled to a common pin terminal, while the pins 1040 in rows 1048a-1048c may each be coupled to a different pin terminal.

A leadframe of semiconductor device assembly 1000 may, therefore, have a greater number of pin terminals on the left side 1012 (e.g. six pin terminals for coupling to the six rows 1044a-1044f of pins 1040) than on the right side 1014 of the module 1008 (four pin terminals for coupling to the four rows 1048 of pins 1040) and base 1020a may have a corresponding greater number of pin terminal openings than base 1020b.

The pin assemblies 1010a, 1010b have a corresponding width, Wa, Wb, and length, La, Lb. The lengths La, Lb of the pin assemblies 1010 are substantially the same, and the lengths may be substantially the same as a length, Lm, of module 1008. In an example the width, Wb, of pin assembly 1010b is substantially the same as the width, Wa, of pin assembly 1010a.

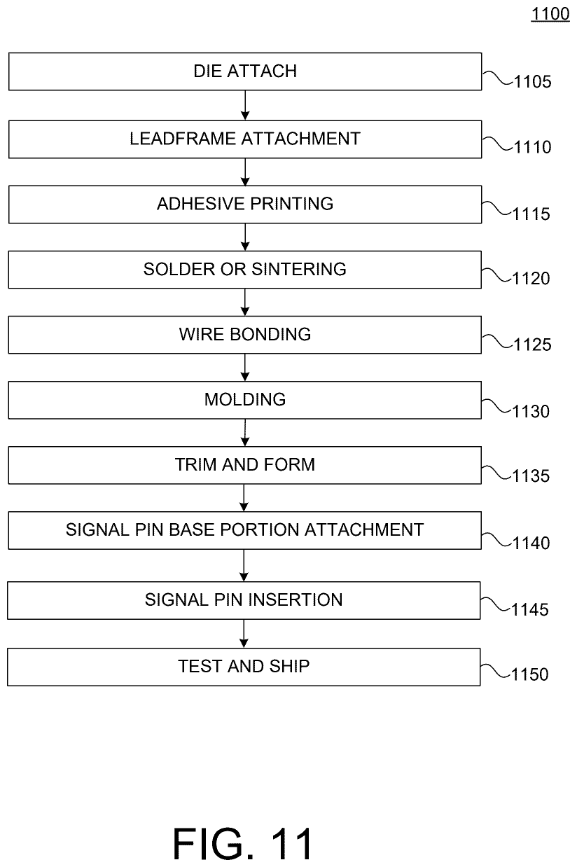

FIG. 11 is a flowchart illustrating an example method 1100 for producing a semiconductor device assembly, such as the assembly 100 of FIGS. 1B to 1D (and the various sub-assemblies described herein). Accordingly, for purposes of illustration, the method 1100 is described with further reference to FIG. 1B to FIG. 7.

At operation 1105, the method includes attaching semiconductor die, e.g., to a substrate. For instance, the operation 1105 can include depositing (printing, dispensing, placing, etc.) an adhesive material on the substrate 605 of the substrate assembly 604, e.g., on the metal layer 610a and the metal layer 610b. After application of the adhesive material, which can be a solder preform, solder paste, a sintering preform, sintering paste, and/or other conductive adhesive material, the plurality of semiconductor die 625 and the plurality of semiconductor die 635 can be positioned (placed, etc.) on corresponding portions of the deposited adhesive material.

At operation 1110, the method may include attaching the leadframe 602 with the substrate assembly 604, such as in the arrangement shown in FIG. 6B.

At operation 1115, the method 1100 may include an adhesive printing operation (or dispensing operation) to apply conductive adhesive for attachment of conductive clips to the leadframe 602 and respective contact pads on the plurality of semiconductor die 625 and the plurality of semiconductor die 635. At operation 1120, the method may include a soldering and/or sintering operation to couple (physically and electrically) the components of the substrate assembly 604 and leadframe 602 with each other with the conductive adhesives of operations 1105 and 1115. In some implementations, operations other than soldering or sintering can be performed, such as a cure operation for a conductive epoxy adhesive.

At operation 1125, bond wires, e.g., bond wires 640 may be used to form wire bonds.

At operation 1130, the method 1100 may include a molding operation (e.g., transfer molding) to apply a molding compound, for example to form the molding compound 130 of the module 108 and the base 120 of the pin assemblies 110.

At operation 1135, the method 1100 may include a trim and form operation, which can include removal of tie bars 624 of the leadframe 602 and in some examples, forming (e.g., bending) of terminals, such as the terminal 105a.

At operation 1140, the method may include attachment of the bases of the pin assemblies 110 to module 108. For example, the pin terminals 202 of module 108 may be inserted into the plurality of pin terminal openings 226 of the bases 120 until the sides of the bases 120 are coupled and engaged with the sides 206a, 206b of the module 108.

At operation 1145, the method 1100 may include inserting the pins 140 in the plurality of pin sockets 135 of the pin assemblies 110 and into the openings 212 of corresponding pin terminals 202.

At operation 1150, the completed semiconductor device assembly 100 can be functionally tested and then shipped, e.g., to a customer for inclusion in a corresponding electrical or electronic system.

In some aspects, the techniques described herein relate to a semiconductor device assembly, including: a module that includes: a semiconductor die electrically coupled with a substrate; a leadframe coupled with the substrate and the semiconductor die; and a molding compound encapsulating the substrate, the semiconductor die and the leadframe, wherein the leadframe includes a pin terminal extending from the molding compound; and a pin assembly including: a base coupled to the module; and a pin disposed in a pin socket of the base; wherein the pin terminal is inserted into the base and a terminal end of the pin is coupled to the pin terminal.

In some aspects, the techniques described herein relate to a semiconductor device assembly, wherein the base includes a pin terminal opening, wherein the pin terminal is inserted into the pin terminal opening.

In some aspects, the techniques described herein relate to a semiconductor device assembly, wherein the molding compound is a first molding compound, the base is formed of a second molding compound.

In some aspects, the techniques described herein relate to a semiconductor device assembly, wherein a first side of the base is in contact with a second side of the module, the first side and the second side forming an interface that extends between a front side and a rear side of the module.

In some aspects, the techniques described herein relate to a semiconductor device assembly, further including at least one of an adhesive or sealant applied at the interface.

In some aspects, the techniques described herein relate to a semiconductor device assembly, wherein the molding compound is a first molding compound, the base is formed of a second molding compound, the second molding compound of the base defining an interface with the first molding compound of the module.

In some aspects, the techniques described herein relate to a semiconductor device assembly, wherein the pin locks the base to the module when the pin is disposed in the pin socket and coupled to the pin terminal.

In some aspects, the techniques described herein relate to a semiconductor device assembly, wherein the module includes a front side, a rear side, a first side and a second side, wherein the pin assembly is coupled to the first side of the module.

In some aspects, the techniques described herein relate to a semiconductor device assembly, wherein the substrate includes a metal layer that is located on the rear side of the module, wherein the metal layer is configured to be coupled to a heat dissipation component.

In some aspects, the techniques described herein relate to a semiconductor device assembly, wherein the pin is a press-fit pin that extends vertically from the base of the pin assembly and is substantially perpendicular to the metal layer.

In some aspects, the techniques described herein relate to a semiconductor device assembly, wherein the first side of the module includes at least one recess or protrusion, wherein the base includes at least one recess or protrusion, wherein the at least one recess or protrusion of the module is configured to engage the at least one recess or protrusion of the base when the base is coupled to the module.

In some aspects, the techniques described herein relate to a semiconductor device assembly, wherein the pin includes a non-conductive body having a first end and a second end, wherein the first end has a shape that is complementary to a shape of the pin socket.

In some aspects, the techniques described herein relate to a semiconductor device assembly, wherein the second end of the non-conductive body is configured to engage a pin guide of a socket of an electrical system.

In some aspects, the techniques described herein relate to a semiconductor device assembly, wherein the second end of the non-conductive body has a shape that is complementary to a shape of the pin guide.

In some aspects, the techniques described herein relate to a pin assembly, including: a base that includes a pin socket in a top side of the base and a pin terminal opening in a first side of the base; and a pin configured to be disposed in the pin socket, wherein the pin includes a non-conductive body that is configured to be inserted into the pin socket; wherein the pin terminal opening intersects the pin socket and is configured to receive a pin terminal of a semiconductor device assembly for coupling the pin to the pin terminal.

In some aspects, the techniques described herein relate to a pin assembly, wherein the first side of the base includes at least one recess or protrusion that is configured to engage at least one recess or protrusion of a module of a semiconductor device assembly when the base is coupled to the module.

In some aspects, the techniques described herein relate to a semiconductor device assembly, wherein the non-conductive body is configured to engage a pin guide of a socket of an electrical system.

In some aspects, the techniques described herein relate to a semiconductor device assembly, wherein an end of the non-conductive body has a shape that is complementary to a shape of the pin guide.

In some aspects, the techniques described herein relate to a method for producing a semiconductor device assembly, the method including: electrically coupling a semiconductor die with a substrate; coupling a leadframe with the substrate; applying a molding compound to the leadframe and the substrate to form a module that includes a pin terminal extending from a side of the module; coupling a base of a pin assembly to the module by inserting the pin terminal into the base; inserting a pin into a pin socket of the base; and coupling the pin to an end portion of the pin terminal located in the base.

In some aspects, the techniques described herein relate to a method, wherein the coupling the base of the pin assembly to the module includes inserting the pin terminal into a pin terminal opening of the base.

In some aspects, the techniques described herein relate to a method, wherein the coupling the pin to an end portion of the pin terminal includes inserting a terminal end of the pin into an opening in the pin terminal.

In some aspects, the techniques described herein relate to a method, further including applying a molding compound to form the base.

In some aspects, the techniques described herein relate to a method, wherein the coupling the leadframe with the substrate includes coupling a module portion of the leadframe to the substrate, wherein the leadframe includes a pin assembly portion, the method further including applying a molding compound to the pin assembly portion to form the base of the pin assembly.

In some aspects, the techniques described herein relate to a method, further including applying a molding compound to a pin frame assembly to form a non-conductive body on the pin.

In some aspects, the techniques described herein relate to a method, wherein the inserting the pin into the pin socket of the base includes inserting the non-conductive body into the pin socket.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly, comprising:
a module that includes:
a semiconductor die electrically coupled with a substrate;
a leadframe coupled with the substrate and the semiconductor die; and
a molding compound encapsulating the substrate, the semiconductor die and the leadframe, wherein the leadframe includes a pin terminal extending from the molding compound; and
a pin assembly including:
a base coupled to the module; and
a pin disposed in a pin socket of the base;
wherein the pin terminal is inserted into the base and a terminal end of the pin is coupled to the pin terminal.

2. The semiconductor device assembly of claim 1, wherein the base includes a pin terminal opening, wherein the pin terminal is inserted into the pin terminal opening.

3. The semiconductor device assembly of claim 1, wherein the molding compound is a first molding compound, the base is formed of a second molding compound.

4. The semiconductor device assembly of claim 3, wherein a first side of the base is in contact with a second side of the module, the first side and the second side forming an interface that extends between a front side and a rear side of the module.

5. The semiconductor device assembly of claim 4, further comprising at least one of an adhesive or sealant applied at the interface.

6. The semiconductor device assembly of claim 1, wherein the molding compound is a first molding compound, the base is formed of a second molding compound, the second molding compound of the base defining an interface with the first molding compound of the module.

7. The semiconductor device assembly of claim 1, wherein the pin locks the base to the module when the pin is disposed in the pin socket and coupled to the pin terminal.

8. The semiconductor device assembly of claim 1, wherein the module includes a front side, a rear side, a first side and a second side, wherein the pin assembly is coupled to the first side of the module.

9. The semiconductor device assembly of claim 8, wherein the substrate includes a metal layer that is located on the rear side of the module, wherein the metal layer is configured to be coupled to a heat dissipation component.

10. The semiconductor device assembly of claim 9, wherein the pin is a press-fit pin that extends vertically from the base of the pin assembly and is substantially perpendicular to the metal layer.

11. The semiconductor device assembly of claim 8, wherein the first side of the module includes at least one recess or protrusion, wherein the base includes at least one recess or protrusion, wherein the at least one recess or protrusion of the module is configured to engage the at least one recess or protrusion of the base when the base is coupled to the module.

12. The semiconductor device assembly of claim 1, wherein the pin includes a non-conductive body having a first end and a second end, wherein the first end has a shape that is complementary to a shape of the pin socket.

13. The semiconductor device assembly of claim 12, wherein the second end of the non-conductive body is configured to engage a pin guide of a socket of an electrical system.

14. The semiconductor device assembly of claim 13, wherein the second end of the non-conductive body has a shape that is complementary to a shape of the pin guide.

15. A pin assembly, comprising:
a base that includes a pin socket in a top side of the base and a pin terminal opening in a first side of the base; and
a pin configured to be disposed in the pin socket, wherein the pin includes a non-conductive body that is configured to be inserted into the pin socket;
wherein the pin terminal opening intersects the pin socket and is configured to receive a pin terminal of a semiconductor device assembly for coupling the pin to the pin terminal.

16. The pin assembly of claim 15, wherein the first side of the base includes at least one recess or protrusion that is configured to engage at least one recess or protrusion of a module of a semiconductor device assembly when the base is coupled to the module.

17. The semiconductor device assembly of claim 16, wherein the non-conductive body is configured to engage a pin guide of a socket of an electrical system.

18. The semiconductor device assembly of claim 17, wherein an end of the non-conductive body has a shape that is complementary to a shape of the pin guide.

19. A method for producing a semiconductor device assembly, the method comprising:
electrically coupling a semiconductor die with a substrate;
coupling a leadframe with the substrate;
applying a molding compound to the leadframe and the substrate to form a module that includes a pin terminal extending from a side of the module;
coupling a base of a pin assembly to the module by inserting the pin terminal into the base;
inserting a pin into a pin socket of the base; and
coupling the pin to an end portion of the pin terminal located in the base.

20. The method of claim 19, wherein the coupling the base of the pin assembly to the module includes inserting the pin terminal into a pin terminal opening of the base.

21. The method of claim 20, wherein the coupling the pin to an end portion of the pin terminal includes inserting a terminal end of the pin into an opening in the pin terminal.

22. The method of claim 19, further comprising applying a molding compound to form the base.

23. The method of claim 22, wherein the coupling the leadframe with the substrate includes coupling a module portion of the leadframe to the substrate, wherein the leadframe includes a pin assembly portion, the method further including applying a molding compound to the pin assembly portion to form the base of the pin assembly.

24. The method of claim 19, further comprising applying a molding compound to a pin frame assembly to form a non-conductive body on the pin.

25. The method of claim 24, wherein the inserting the pin into the pin socket of the base includes inserting the non-conductive body into the pin socket.
